(19) United States
(12) Patent Application Publication
(10) Pub. No.: US 2020/0127558 A1
(43) Pub. Date: Apr. 23, 2020

(54) LOAD DRIVER CIRCUIT

(71) Applicant: FUJI ELECTRIC CO., LTD., Kawasaki-shi (JP)

(72) Inventors: Kenji FUJITSU, Nagoya-city (JP); Morio IWAMIZU, Matsumoto-city (JP); Shigeyuki TAKEUCHI, Matsumoto-city (JP)

(73) Assignee: FUJI ELECTRIC CO., LTD., Kawasaki-shi (JP)

(21) Appl. No.: 16/588,076

(22) Filed: Sep. 30, 2019

(30) Foreign Application Priority Data
Oct. 18, 2018 (JP) 2018-196694

(51) Int. Cl. H02M 3/07; H03K 3/03

(52) U.S. Cl. CPC H02M 3/07; H03K 3/0315

(57) ABSTRACT

A load driver circuit including an oscillator circuit configured to generate a clock, a charge pump circuit configured to receive the clock and operate according to the clock, and a boosting-capability control circuit configured to control the boosting capability of the charge pump circuit according to a value of an output voltage of the charge pump circuit.

### CROSS REFERENCE TO RELATED APPLICATIONS

This application is based upon and claims the benefit of priority of the prior Japanese Patent Application No. 2018-196694, filed on Oct. 18, 2018, the entire contents of which are incorporated herein by reference.

### BACKGROUND OF THE INVENTION

### 1. Field of the Invention

Embodiments of the invention relate to a load driver circuit.

### 2. Description of the Related Art

Conventionally, many load driver circuits are equipped on automobiles for switching control of a load such as that of a motor. As such a load driver circuit, often types that drive a load are used and are disposed on a high-side of the load. FIG. 6 is a diagram depicting a circuit configuration of a conventional high-side IPS. A high-side intelligent power switch (IPS) 1300 integrates an output-stage power metal-oxide-semiconductor field-effect transistor (MOSFET) and control/protection circuit on a single chip.

In the circuit configuration depicted in FIG. 6, an output-stage MOSFET 1111 is turned ON or OFF based on a signal input to an input terminal (IN), thereby actuating a load (not depicted) of a motor, solenoid, etc. connected to an output terminal (OUT). VCC is a terminal that supplies power supply voltage and ST is a load-state output terminal.

The circuit configuration depicted in FIG. 6 includes protective functions of an open-load detection circuit that detects load shorts, an overcurrent detection circuit that detects overcurrent, and an overheating detection circuit that detects overheating; and when an abnormality occurs in an electrical system, self-protection thereof is possible. Furthermore, since the load-state output terminal is included, protection can be implemented instantly when an abnormality occurs in the electrical system, the abnormal state can be communicated to a microcomputer (CPU) and reflected in control to increase redundancy in the system. Further, a level shift circuit (a level shift driver 1200) is built in to set the output-stage MOSFET 1111 in a full ON state.

FIG. 7 is a diagram depicting operation of the level shift circuit in the conventional high-side IPS circuit. In FIG. 7, “out” is an output terminal of a high-side IPS 1300. In FIG. 7, resistance is connected as a load. Power supply voltage Vcc is applied to a drain of the output-stage MOSFET 1111. At the output-stage MOSFET 1111, voltage Vout of an output terminal_out is set to have a same voltage value as the power supply voltage Vcc, whereby operation becomes stable and has low loss. Therefore, at the high-side IPS 1300, the output-stage MOSFET 1111 is set in a complete (full) ON state which requires applying to a gate (gs), voltage that is at least a threshold value (Vth) with respect to a source (out) of the output-stage MOSFET 1111. Thus, in such a circuit configuration, a charge pump circuit (CP circuit) is provided in the level shift circuit 1200 and the output-stage MOSFET 1111 is driven by voltage (for example, Vcc+10V) that has been increased to at least equal to Vcc.

FIG. 8 is a diagram depicting a configuration of a conventional level shift circuit. The level shift circuit 1200 includes a charge pump circuit 1100 and an oscillator circuit 1150. The charge pump circuit 1100 uses a clock signal from the oscillator circuit 1150 to boost and output input voltage. FIG. 9 is a diagram of an output waveform of the oscillator circuit of the conventional level shift circuit. The oscillator circuit 1150 outputs a clock signal according to which voltage periodically assumes a high state (H) or a low state (L).

At the charge pump circuit 1100, inverters 1120, 1121 are alternately turned ON and OFF by the clock signal from the oscillator circuit 1150. Diodes 1140, 1141 are turned ON and Vcc is held in capacitors 1130, 1131 by H of the clock signal. Further, diodes 1142, 1143 are turned ON and the voltage held in the capacitors 1130, 1131 is output by L of the clock signal.

FIG. 10 is a diagram of an output waveform of a conventional charge pump circuit. As depicted in FIG. 10, a GS voltage is boosted stepwise by switching between L and H of the clock signal. Further, a device (not depicted) that protects the gate of the output-stage MOSFET 1111 is integrated in the charge pump circuit 1100 and output voltage of the charge pump circuit 1100 is saturated when reaching a certain value. Further, to turn ON the high-side IPS 1300 rapidly, for example, the charge pump circuit 1100 of the high-side IPS 1300 is equipped with the oscillator circuit 1150 having a period of at least 1 MHz and implements high-speed boosting.

Further, according to a known technique, for power saving of a charge pump circuit, operation of the charge pump circuit is controlled according output of a flipflop FF that is set by A_point voltage becoming H and that is reset by B_point voltage becoming L, whereby operation of the charge pump circuit is effectively turned ON/OFF, saving energy (for example, refer to Japanese Laid-Open Patent Publication No. 2005-57973).

### SUMMARY OF THE INVENTION

According to an embodiment of the invention, a load driver circuit includes an oscillator circuit configured to generate a clock; a charge pump circuit configured to operate according to input of the clock; and a boosting-capability control circuit configured to control a boosting capability of the charge pump circuit according to an output voltage value of the charge pump circuit.

In the embodiment, the boosting-capability control circuit, when the output voltage value is at least a reference value, decreases the boosting capability of the charge pump circuit by decreasing an oscillation frequency of the clock.

In the embodiment, the boosting-capability control circuit, when the output voltage value is lower than a reference value, enhances the boosting capability of the charge pump circuit by increasing an oscillation frequency of the clock.

In the embodiment, the oscillator circuit has an odd number of inverters connected in a ring-shape, and at least one capacitor connected to at least one output terminal of the odd number of inverters. The boosting-capability control circuit, when the output voltage value is at least the reference value, increases a capacitance of the at least one capacitor of the oscillator circuit and thereby, decreases the oscillation frequency of the clock generated by the oscillator circuit.

In the embodiment, the oscillator circuit has an odd number of inverters connected in a ring-shape, and at least one capacitor connected to at least one output terminal of the odd number of inverters. The boosting-capability control circuit, when the output voltage value is lower than the reference value, decreases a capacitance of the at least one capacitor of the oscillator circuit and thereby, increases the oscillation frequency of the clock generated by the oscillator circuit.

In the embodiment, the boosting-capability control circuit, when the output voltage value is at least a reference value, reduces a quantity of charge pump stages of the charge pump circuit and thereby, reduces the boosting capability of the charge pump circuit.

In the embodiment, the boosting-capability control circuit, when the output voltage value is lower than a reference value, increases a quantity of charge pump stages of the charge pump circuit and thereby, enhances the boosting capability of the charge pump circuit.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is diagram depicting a configuration of a load driver circuit 1 according to a first embodiment.

FIG. 2 is diagram depicting a configuration of an oscillator circuit according to the first embodiment.

FIG. 3 is a diagram depicting output waveforms of the oscillator circuit according to the first embodiment.

FIG. 4 is a diagram depicting output waveforms of a charge pump circuit according to the first embodiment.

FIG. 5 is diagram depicting a circuit configuration of a load driver circuit according to a second embodiment.

FIG. 6 is a diagram depicting a circuit configuration of a conventional high-side IPS.

FIG. 7 is a diagram depicting operation of a level shift circuit in the conventional high-side IPS circuit.

FIG. 8 is a diagram depicting a configuration of a conventional level shift circuit.

FIG. 9 is a diagram of an output waveform of an oscillator circuit of the conventional level shift circuit.

FIG. 10 is a diagram of an output waveform of a conventional charge pump circuit.

### DETAILED DESCRIPTION OF THE INVENTION

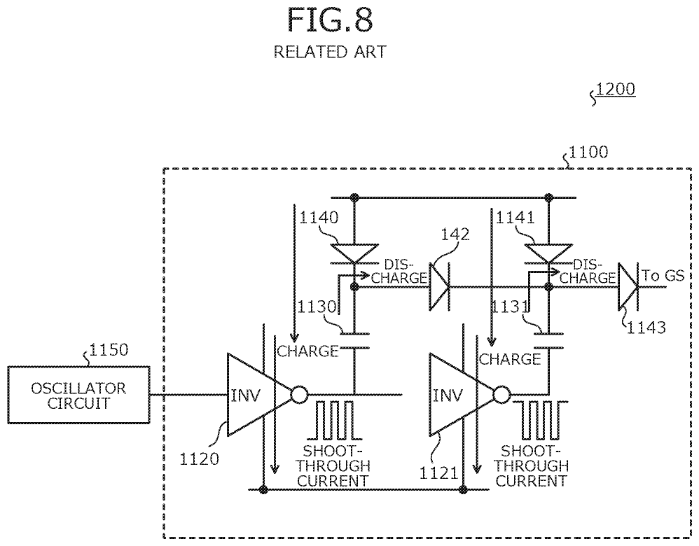

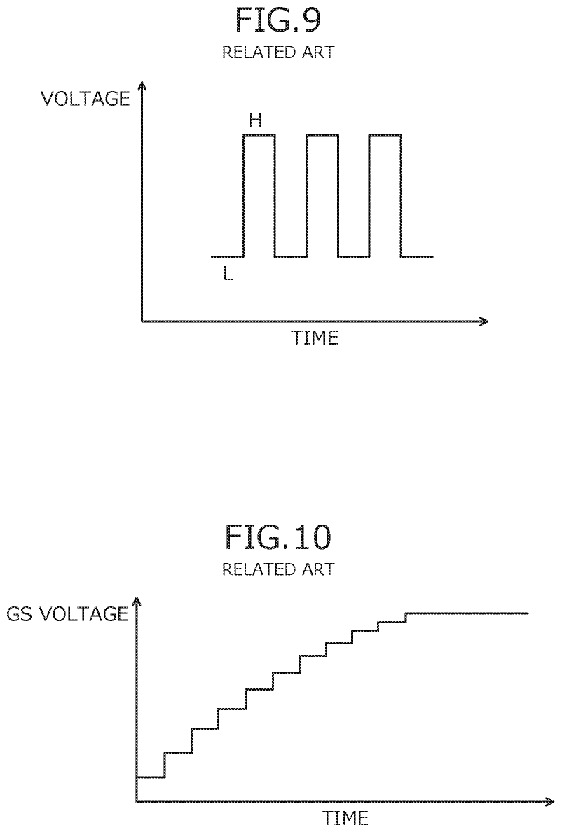

First problems associated with the conventional techniques will be discussed. When the charge pump circuit 1100 is driven, as depicted in FIG. 8, large shoot-through current flows in the inverters 1120, 1121 and large current that charges/discharges the capacitors 1130, 1131 flows. Therefore, with the recent interest in power saving, the current consumed by the charge pump circuit 1100 cannot be ignored.

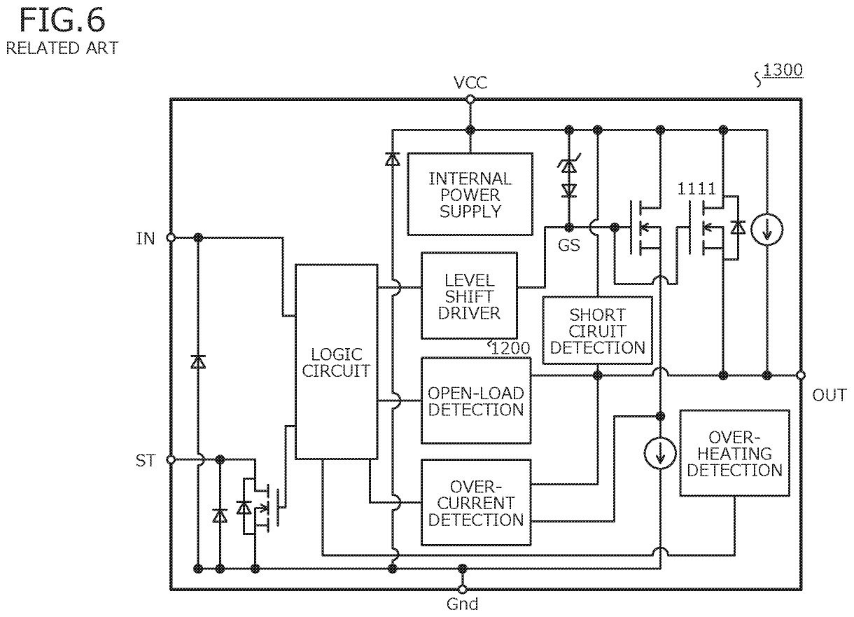

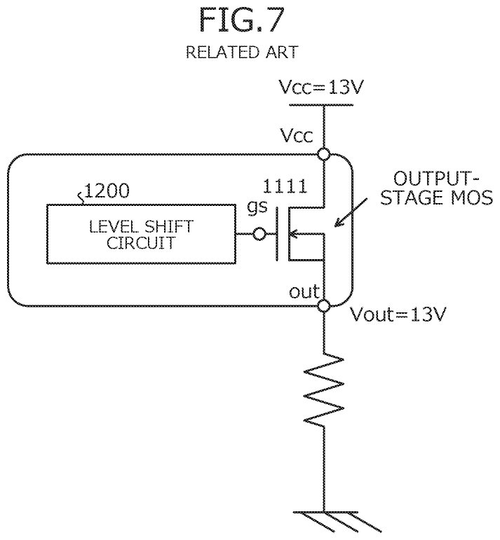

For power saving of the charge pump circuit 1100, in Japanese Laid-Open Patent Publication No. 2005-57973, a circuit is proposed that suspends charge pump operation when boosting is sufficient. Accordingly, in Japanese Laid-Open Patent Publication No. 2005-57973, the output voltage has a mixture of high states and low states. Therefore, when the circuit configuration in Japanese Laid-Open Patent Publication No. 2005-57973 is applied as is to the high-side IPS and gate voltage (output of the charge pump circuit 1100) of the output-stage MOSFET 1111 depicted in FIG. 6 is high, a turn-OFF period increases and when the gate voltage (output of the charge pump circuit 1100) is low, the turn-OFF period decreases, which contributes to large variation of switching characteristics. Therefore, the circuit configuration in Japanese Laid-Open Patent Publication No. 2005-57973 cannot be used in the high-side IPS.

Embodiments of a load driver circuit according to the present invention will be described in detail with reference to the accompanying drawings. However, the following embodiments do not limit the claimed invention. Further, not all combinations of features described in the embodiments are essential to the invention.

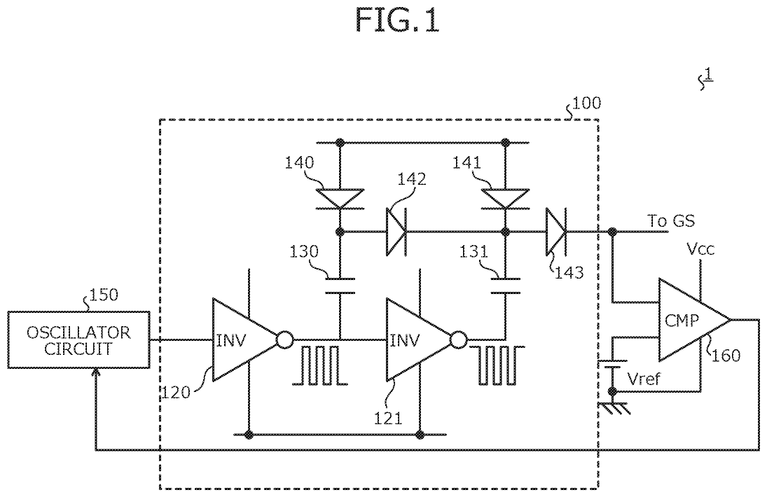

FIG. 1 is diagram depicting a configuration of a load driver circuit 1 according to a first embodiment. FIG. 1 is diagram depicting a configuration of a portion in the load driver circuit 1 corresponding to a level shift circuit 200. In the load driver circuit 1 according to the first embodiment, a charge pump circuit 100, the oscillator circuit 150, and a comparator (CMP) 160 are included.

The charge pump circuit 100 includes built-in inverters 120, 121, diodes 140, 141, 142, 143, and capacitors 130, 131. The charge pump circuit 100, similarly to the conventional charge pump circuit 1100, uses a clock signal from the oscillator circuit 150 to boost and output input voltage.

The comparator (CMP) (boosting-capability control circuit) 160 that monitors output voltage of the charge pump circuit 100 is built into the load driver circuit 1 depicted in FIG. 1. The output voltage of the charge pump circuit 100 and a reference voltage Vref are connected to the comparator 160 and compared. The reference voltage Vref is a voltage having at least a threshold value (Vth) necessary to set an output-stage MOSFET of a high-side IPS in a completely ON state. The comparator 160 compares the output voltage of the charge pump circuit 100 and Vref, and when the output voltage of the charge pump circuit 100 is at least equal to Vref, outputs a signal that decreases a frequency of the oscillator circuit 150. Conversely, when the output voltage of the charge pump circuit 100 is lower than Vref, the comparator 106 outputs a signal that increases the frequency of the oscillator circuit 150.

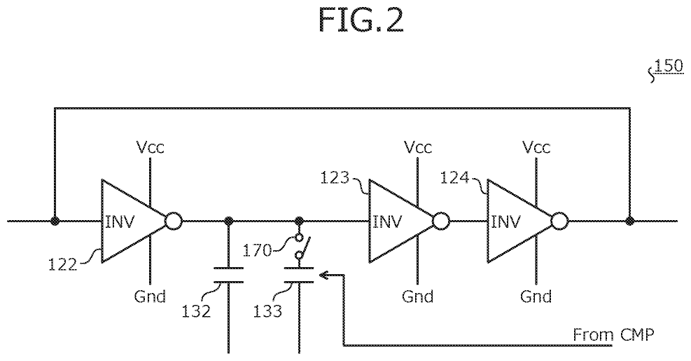

FIG. 2 is diagram depicting a configuration of the oscillator circuit according to the first embodiment. FIG. 2 depicts a ring oscillator having a configuration that uses an odd number of inverters. The ring oscillator depicted in FIG. 2 has three inverters 122, 123, 124 connected in a ring-shape, and capacitors 132, 133 each connected to an output terminal of the inverter 122. Further, a switch 170 that can be turned ON and OFF by the comparator 160 is connected to the capacitor 133.

In the ring oscillator configured as such, output of the inverter 124 at a last stage is input to the inverter 122 at a first stage, thereby forming a ring-structure overall. The inverters 122, 123, 124 have a finite delay period and therefore, oscillate by recursively performing a process in which when the finite delay period elapses from the input to the inverter 122 at the first stage, the inverter 124 at the last stage outputs a logical NOT of the first stage input, which is again input to the inverter 122 at the first stage.

In the ring oscillator depicted in FIG. 2, for example, when output from the comparator 160 is ON, the switch 170 is turned ON, and when the output from the comparator 160 is OFF, the switch 170 is turned OFF. When the switch 170 turns ON, capacitance of the capacitor 133 is connected, a delay period between the inverter 122 and the inverter 123 increases, and oscillation frequency decreases. Conversely, when the switch 170 turns OFF, the oscillation frequency increases. For example, by turning ON the switch 170 with capacitances of the capacitors 132, 133 being about the same, the oscillation frequency becomes about half when capacitance between the inverter 122 and the inverter 123 about doubles.

Therefore, when the output voltage of the charge pump circuit 100 is at least equal to Vref, the comparator 160 turns ON the switch 170 of the ring oscillator, whereby the frequency of the oscillator circuit 150 may be reduced. Further, when the output voltage of the charge pump circuit 100 is lower than Vref, the switch 170 of the ring oscillator is turned OFF, whereby the frequency of the oscillator circuit 150 may be increased.

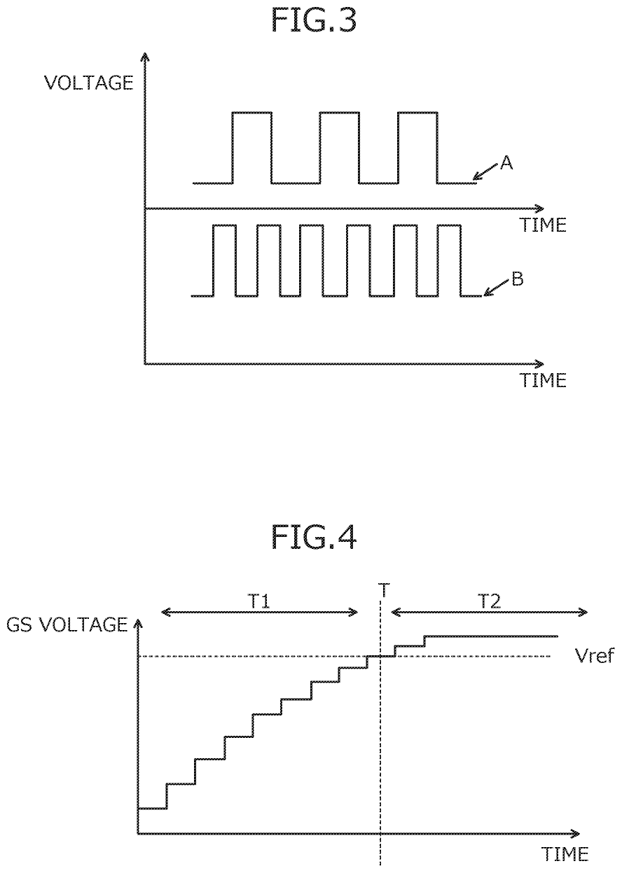

FIG. 3 is a diagram depicting output waveforms of the oscillator circuit according to the first embodiment. A waveform A is an output waveform when the frequency of the oscillator circuit 150 has been reduced and a waveform B is an output waveform when the frequency of the oscillator circuit 150 has been increased.

In the load driver circuit 1 depicted in FIG. 1, first, to obtain sufficient switching speed at turn-ON, for example, the frequency of the oscillator circuit 150 is increased like the waveform B in FIG. 3, establishing a boosting capability of the charge pump circuit 100. FIG. 4 is a diagram depicting output waveforms of the charge pump circuit 100 according to the first embodiment. Since the boosting capability is established, the output voltage is boosted as depicted during an interval T1 shown in FIG. 4.

Next, the output voltage of the charge pump circuit 100 increases and when the output voltage becomes at least equal to Vref at time T depicted in FIG. 4, the comparator 160 outputs a signal that decreases the frequency of the oscillator circuit 150. For example, similarly to the waveform A in FIG. 3, the frequency of the oscillator circuit 150 is reduced and the boosting capability is reduced. As a result, shoot-through current of the inverters 120, 121 and current that charges/discharges the capacitors 130, 131 decrease, and power consumption in the charge pump circuit 100 decreases.

Here, in the charge pump circuit 100, when the boosting capability disappears, the output voltage gradually decreases due to leak current. When the output voltage becomes low, the turn-OFF period is shortened and switching characteristics vary. Therefore, the frequency of the oscillator circuit 150 may be set at a frequency whereby the output voltage is maintained at a constant value without decreasing below Vref, i.e., may be a frequency having a boosting capability of compensating the amount of decrease of the output voltage due to leak current. This frequency is dependent on the amount of leak current, the value of the power supply voltage Vcc, and capacitance of the capacitor of the charge pump circuit 100, etc. and therefore, although different for each circuit, by setting such a frequency, the output voltage may be maintained at a constant value that is at least equal to Vref such as during an interval T2 depicted in FIG. 4, the turn-OFF period becomes constant, and variation of switching characteristics may be suppressed.

In the case described above, when the output voltage of the charge pump circuit 100 becomes at least equal to Vref, the output voltage is maintained at a constant value that is at least equal to Vref. In this case, the output voltage does not become lower than Vref and therefore, a function of turning ON the switch 170 of the ring oscillator when the output voltage of the charge pump circuit 100 to the comparator 160 is lower than Vref may be omitted.

Further, not setting a frequency as described above is also possible. When the output voltage of the charge pump circuit 100 decreases and the output voltage becomes lower than Vref, the comparator 160 outputs signal that increases the frequency of the oscillator circuit 150. For example, the frequency of the oscillator circuit 150 is increased similarly to the waveform B depicted in FIG. 3 and the boosting capability is increased. As a result, the output voltage may be boosted again. In this case as well, since operation of the charge pump circuit 100 is not suspended, even when the output voltage becomes lower than Vref, boosting is possible right away, the output voltage does not have a mixture of high states and low states, and switching characteristics do not vary greatly.

Conversely, in cases where the output voltage does not become a constant value and continues to increase even when the oscillation frequency of the oscillator circuit 150 is reduced, similarly to the conventional technique, the output voltage of the charge pump circuit 100 is saturated when reaching a certain value by a device that protects a gate of an output-stage MOSFET 111. In this case, unnecessary current flows in the charge pump circuit 100 and therefore, the oscillation frequency of the oscillator circuit 150 may be further reduced.

Further, in the first embodiment above, although the boosting capability of the charge pump circuit 100 is reduced, oscillation of the oscillator circuit 150 may be suspended and the boosting capability of the charge pump circuit 100 may be suspended. In this case, when the boosted output voltage becomes lower than Vref, the comparator 160 resumes the oscillation of the oscillator circuit 150 and again implements boosting. The oscillation frequency at this time may be reduced below an initial frequency of the waveform B in FIG. 3. As a result, even when boosting is again implemented, lower current consumption is possible.

In the first embodiment above, while a case in which the ring oscillator is used as the oscillator circuit 150 is described as an example, another oscillator circuit capable to reducing the oscillation frequency by a signal from the comparator 160 may be used.

As described above, according to the load driver circuit of the first embodiment, when boosted voltage becomes at least equal to Vref, the frequency of the oscillator circuit is reduced and the boosting capability of the charge pump circuit is reduced. Therefore, when the voltage is at least equal to Vref, the shoot-through current of the inverters and current charging/discharging the capacitor decrease, and power consumption in the charge pump circuit decreases. Further, since the output voltage has a constant value at least equal to Vref, the turn-OFF period becomes constant, enabling variation of switching characteristics to be suppressed.

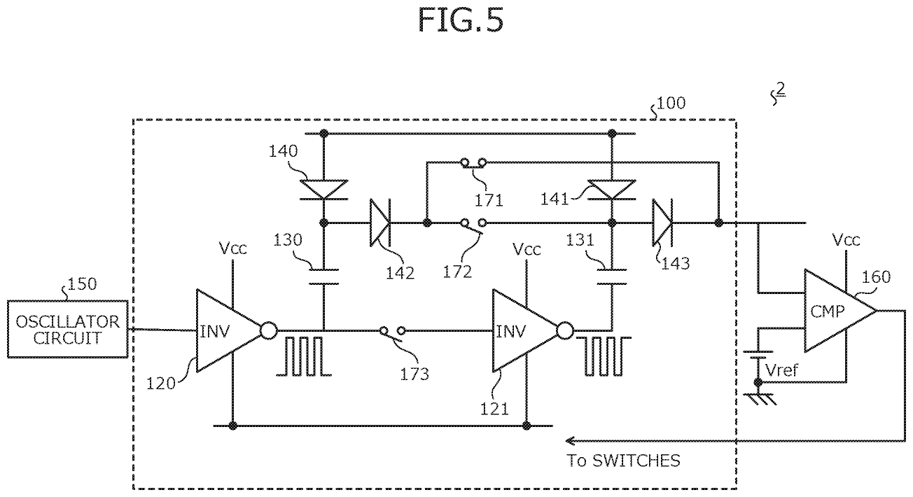

FIG. 5 is diagram depicting a circuit configuration of a load driver circuit according to a second embodiment. In a load driver circuit 2 depicted in FIG. 5, operations and components substantially identical to those of the load driver circuit 1 according to the first embodiment depicted in FIG. 1 are assigned the same reference numerals used in the first embodiment and description thereof is omitted hereinafter. In the load driver circuit 2 according to the second embodiment, the charge pump circuit 100 includes switches 171, 172, 173, and the comparator 160 is connected to the switches 171, 172, 173 in the charge pump circuit 100.

The comparator 160 compares the output voltage of the charge pump circuit 100 and Vref. When the output voltage of the charge pump circuit 100 is lower than Vref, the comparator 160 turns OFF the switch 171 and turns ON the switches 172, 173. On the other hand, when the output voltage of the charge pump circuit 100 is at least equal to Vref, the comparator 160 turns ON the switch 171 and turns OFF the switches 172, 173 (state depicted in FIG. 5).

In the load driver circuit 2 depicted in FIG. 5, first, at the time of turn-ON, to obtain sufficient switching speed, the comparator 160 turns OFF the switch 171 and turns ON the switches 172, 173. As a result, boosting is not performed at the capacitors 130, 131, the boosting capability of the charge pump circuit 100 is increased, and the output voltage of the charge pump circuit 100 is increased. An output waveform of the charge pump circuit 100 according to the second embodiment is identical to the output waveform in the first embodiment and therefore, is not depicted in the drawings (refer to FIG. 4).

Next, the output voltage of the charge pump circuit 100 is increased and when the output voltage becomes at least equal to Vref, the comparator 160 turns ON the switch 171 and turns OFF the switches 172, 173. As a result, boosting by the capacitor 131 is not performed, the boosting capability of the charge pump circuit 100 decreases, and the shoot-through current of the inverter 121 and current that charges/discharges the capacitor 131 do not flow. Thus, power consumption in the charge pump circuit 100 decreases.

Further, in the example depicted in FIG. 5, while the charge pump circuit 100 has two stages and when the output voltage becomes at least equal to Vref, operation of a downstream stage, a portion including the diodes 141, 143, and the capacitor 131 is suspended, configuration is not limited hereto. For example, configuration may be such that in the charge pump circuit 100 having three stages, when the output voltage becomes at least equal to Vref, the operation of one downstream stage portion or two downstream stage portions is suspended.

Similarly to the first embodiment, when the charge pump circuit 100 has plural stages, the number of suspended stages may be set to a number of stages that maintain the output voltage of the charge pump circuit 100 at a constant value without the output voltage becoming less than Vref. By setting the number of suspended stages in this manner, the output voltage may be maintained at a constant value that is at least equal to Vref like in the interval T2 depicted in FIG. 4, the turn-OFF period becomes constant, and variation of the switching characteristics may be suppressed.

In the case described above, when the output voltage of the charge pump circuit 100 is at least equal to Vref, the output voltage is maintained at a constant value that is at least equal to Vref. In this case, the output voltage does not become lower than Vref and therefore, a function of turning OFF the switch 171 and turning ON the switches 172, 173 when the comparator 160 compares the output voltage of the charge pump circuit 100 and Vref, and the output voltage of the charge pump circuit 100 is lower than Vref may be omitted.

Further, the comparator 160 may turn OFF the switch 171 and turn ON the switches 172, 173 when the number of suspended stages is not set to a number of stages that maintain the output voltage of the charge pump circuit 100 at a constant value, the output voltage of the charge pump circuit 100 decreases, and the output voltage becomes lower than Vref. As a result, the output voltage may be boosted again. In this case as well, since operation of the charge pump circuit 100 is not suspended, even when the output voltage becomes lower than Vref, boosting is possible right away, the output voltage does not have a mixture of high states and low states, and switching characteristics do not vary greatly.

Conversely, in cases where the output voltage does not become a constant value and continues to increase even when the oscillation frequency of the oscillator circuit 150 is reduced, similarly to the conventional technique, the output voltage of the charge pump circuit 100 is saturated when reaching a certain value by a device that protects a gate of the output-stage MOSFET 111. In this case, unnecessary current flows in the charge pump circuit 100 and therefore, the number of suspended stages of the charge pump circuit 100 may be increased.

As described above, according to the load driver circuit of the second embodiment, when boosted voltage becomes at least equal to Vref, the number of operating stages of the charge pump circuit is reduced, and the boosting capability of the charge pump circuit is reduced. Therefore, when the voltage is at least equal to Vref, the shoot-through current of the inverters and current that charges/discharges the capacitor decrease, and power consumption in the charge pump circuit 100 is reduced. Further, since the output voltage is a constant value that is at least equal to Vref, the turn-OFF period becomes constant and switching characteristics do not vary.

In the first and the second embodiments, while a method of reducing the frequency of the oscillator circuit 150 or a method of reducing the number of stages of the charge pump circuit 100 is adopted as a method of reducing the boosting capability of the charge pump circuit 100, the present invention may reduce the boosting capability of the charge pump circuit 100 by another method and achieve similar effects.

In the foregoing, while embodiments are used to describe the present invention, a technical range of the present invention is not limited to the described range in the present embodiments. In the embodiments above, it will be apparent to one skilled in the art that various changes or modifications are possible. It is also apparent from the description of the scope of the claims that the embodiments with such added changes or improvements may be within the technical scope of the present invention. Further, it should be noted that an execution sequence of processes of stages, steps, procedures, operations, etc. in a method, a program, a system, a device shown in the drawings, the specification, and the claims may be performed in any sequence unless clearly specified to be “before”, “prior to”, etc. or output of a previous process is used at a subsequent process. Regarding operation flow in the drawings, specification, and scope of the claims, for the sake of convenience, even when “first”, “next”, or the like is used, this does not mean that implementation in this sequence is essential.

According to the present invention, the load driver circuit reduces the frequency of the oscillator circuit and reduces the boosting capability of the charge pump circuit when the boosted voltage becomes at least equal to Vref. Therefore, when the voltage is at least equal to Vref, the shoot-through current of the inverters and current that charges/discharges the capacitor are reduced, and power consumption in the charge pump circuit is reduced. Further, since the output voltage is a constant value that is at least equal to Vref, the turn-OFF period becomes constant, enabling variation of the switching characteristics to be suppressed.

The load driver circuit according to the present invention enables power consumption in the charge pump circuit to be suppressed without degradation of switching characteristics of the MOSFET.

As described, the load driver circuit according to the present invention is useful for load driver circuits in which a power semiconductor element and a control circuit therefor are integrated on a single chip and is particularly suitable for high-side IPSs that control load switching.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A load driver circuit comprising:
an oscillator circuit configured to generate a clock;
a charge pump circuit configured to receive the clock and operate according to the clock; and
a boosting-capability control circuit configured to control a boosting capability of the charge pump circuit according to an output voltage value of the charge pump circuit.

2. The load driver circuit according to claim 1, wherein
the boosting-capability control circuit, when the output voltage value is at least a reference value, decreases the boosting capability of the charge pump circuit by decreasing an oscillation frequency of the clock.

3. The load driver circuit according to claim 2, wherein
the oscillator circuit has an odd number of inverters connected in a ring-shape, and at least one capacitor connected to an output terminal of one of the odd number of inverters, and
the boosting-capability control circuit, when the output voltage value is at least the reference value, increases a capacitance of the at least one capacitor of the oscillator circuit and thereby, decreases the oscillation frequency of the clock generated by the oscillator circuit.

4. The load driver circuit according to claim 1, wherein
the boosting-capability control circuit, when the output voltage value is lower than a reference value, enhances the boosting capability of the charge pump circuit by increasing an oscillation frequency of the clock.

5. The load driver circuit according to claim 4, wherein
the oscillator circuit has an odd number of inverters connected in a ring-shape, and at least one capacitor connected to an output terminal of one of the odd number of inverters, and
the boosting-capability control circuit, when the output voltage value is lower than the reference value, decreases a capacitance of the at least one capacitor of the oscillator circuit and thereby, increases the oscillation frequency of the clock generated by the oscillator circuit.

6. The load driver circuit according to claim 1, wherein
the boosting-capability control circuit, when the output voltage value is at least a reference value, reduces a quantity of charge pump stages of the charge pump circuit and thereby, reduces the boosting capability of the charge pump circuit.

7. The load driver circuit according to claim 1, wherein the boosting-capability control circuit, when the output voltage value is lower than a reference value, increases a quantity of charge pump stages of the charge pump circuit and thereby, enhances the boosting capability of the charge pump circuit.
